(19) United States
(12) Patent Application Publication
(10) Pub. No.: US 2008/0198565 A1
(43) Pub. Date: Aug. 21, 2008

(54) SURFACE MOUNT FOOT WITH COINED EDGE SURFACE

(75) Inventors: Sheldon Lynn Horst, Columbia, PA (US); John Steven Wilson, Shermansdale, PA (US)

Correspondence Address: TYCO TECHNOLOGY RESOURCES, 4550 NEW LINDEN HILL ROAD, SUITE 140, WILMINGTON, DE, 19808-2952, US

(73) Assignee: TYCO ELECTRONICS CORPORATION, Middletown, PA (US)

(21) Appl. No.: 11/675,716

(22) Filed: Feb. 16, 2007

(51) Int. Cl. H05K 7/14

(52) U.S. Cl. 361/760; 29/825

(57) ABSTRACT

A surface mount device having a surface mount foot and a method for making the same is disclosed. The method includes providing a piece of pre-plated conductive stock of a conductive base material and a corrosion-resistant conductive plating material different from the conductive base material at least partially overlying the conductive base material. The stock is cut and formed to create a surface mount device having a surface mount foot extending therefrom. The surface mount foot has a top surface, a plated bottom surface and an at least one unplated side surface intermediate the top and bottom surfaces. The plated bottom surface is swaged to create a new plated coined edge surface intermediate the unplated side surface and the plated bottom surface of the surface mount foot.

### FIELD OF THE INVENTION

The present invention is generally directed to electrical connectors for use with printed circuit boards and more particularly to surface mount devices having one or more surface mount feet for soldering to electrical devices.

### BACKGROUND OF THE INVENTION

Surface mount devices include connectors commonly used in electronic assemblies that typically utilize one or more feet, referred to as surface mount feet or SMT feet, to which the device is soldered to a printed circuit board (PCB) or other electrical device. Although the stock material from which the SMT devices are formed is conductive, it is generally not corrosion resistant. Corroded surfaces resist wetting of applied solder, resulting in unacceptable solder joints within the IPC industry standard IPC J-STD-001D: “Requirements for Soldered Electrical and Electronic Assemblies” which generally requires wetting angles less than 90°.

To provide suitable solder-ability, current SMT feet are manufactured from unplated sheet stock and then plated, post-manufacturing, with a corrosion resistant material so that all cut and formed surfaces are coated prior to soldering. However, this requires the additional step of post-plating the SMT foot after cutting and forming, adding time and expense to the process.

It would be less expensive to directly cut and form the SMT device containing the SMT foot from pre-plated metal stock. However, in cutting and forming the SMT foot from pre-plated metal stock, some surfaces, including the sides of the foot to which solder is applied, would still have exposed base material due to the profile cutting (or blanking) process and would not be plated. Over time, the exposed, unplated surfaces corrode. As a result, when solder is applied to those unplated, corroded surfaces, the solder does not properly wet the surface and thus does not consistently produce an acceptable solder joint.

What is needed is an SMT foot that can be cut and formed from pre-plated metal stock, reducing post-processing costs, while still providing for an acceptable solder joint.

### SUMMARY OF THE INVENTION

According to an exemplary embodiment of the invention, a surface mount device is disclosed. The surface mount device has at least one surface mount foot extending therefrom, the surface mount foot comprising a conductive base material and a corrosion-resistant conductive material at least partially overlying the conductive base material. The surface mount foot has a top surface, a plated bottom surface, two unplated side surfaces, and at least one plated coined edge surface. The plated coined edge surface is intermediate the plated bottom surface and an unplated side surface.

According to another exemplary embodiment of the invention, a method for making a surface mount device comprises providing a piece of pre-plated conductive sheet stock of a conductive base material and a corrosion-resistant conductive plating material different from the conductive base material overlying the conductive base material and cutting and forming the piece of pre-plated conductive sheet stock to create a surface mount device having a surface mount foot extending therefrom. The surface mount foot has a top surface, a plated bottom surface and at least one unplated side surface intermediate the top surface and the bottom surface. The method further includes swaging the plated bottom surface to create a plated coined edge surface intermediate the unplated side surface and the plated bottom surface of the surface mount foot.

According to another exemplary embodiment of the invention, a method for attaching a surface mount device to an electrical device comprises soldering the surface mount foot made by the foregoing method to the electrical device.

One advantage of exemplary embodiments of the invention is that surface mounted devices suitable for soldering to printed circuit boards can be manufactured using pre-plated stock, which is less expensive than employing subsequent post-processing plating techniques.

Another advantage of exemplary embodiments of the invention is that the surface mount device has a surface mount foot with a plated coined edge surface to which solder will adhere.

Other features and advantages of the present invention will be apparent from the following more detailed description of exemplary embodiments, taken in conjunction with the accompanying drawings which illustrate, by way of example, the principles of the invention.

### BRIEF DESCRIPTION OF THE DRAWINGS

FIG. 1 illustrates a side view of a surface mount connector attached to an electronic device in accordance with an exemplary embodiment of the invention.

FIG. 2 illustrates an isometric view of a portion of a surface mount connector in accordance with an exemplary embodiment of the invention.

FIG. 3 illustrates a front elevation of a surface mount foot in accordance with an exemplary embodiment of the invention.

FIG. 4 illustrates a perspective view of a surface mount foot at an intermediate step in a method according to an exemplary embodiment of the invention.

FIG. 5 illustrates a sheet of pre-plated stock for use in accordance with exemplary embodiments of the invention.

Where like parts appear in more than one drawing, it has been attempted to use like reference numerals for clarity.

### DETAILED DESCRIPTION OF EXEMPLARY EMBODIMENTS

Exemplary embodiments of the invention are directed to surface mount devices, including connectors for use in electronic assemblies, having one or more surface mount feet by which the device is soldered to a printed circuit board or other electronic device.

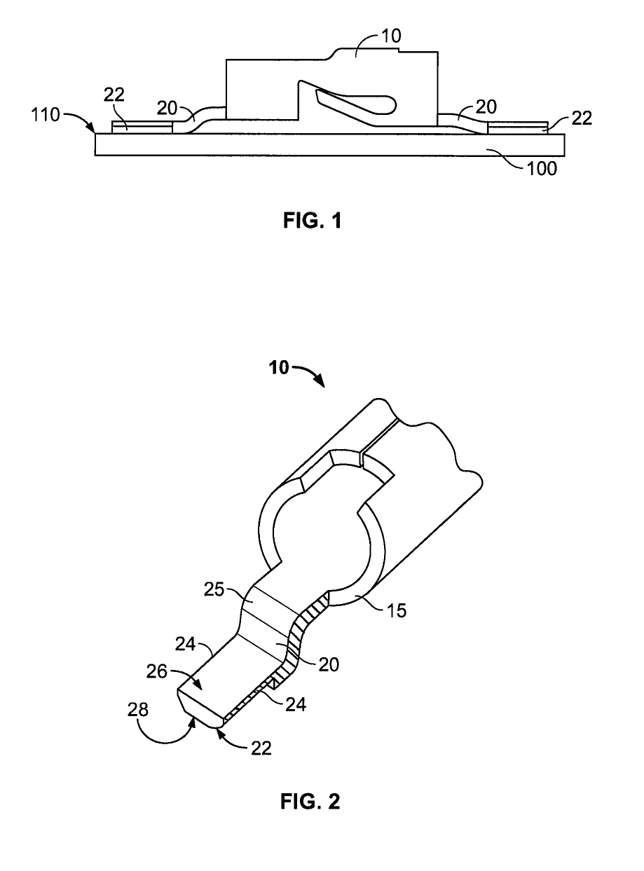

Turning to FIG. 1, a surface mount (SMT) connector 10 is mounted on a printed circuit board 100 by solder connections (omitted for clarity) to one or more SMT feet 20 in contact with a surface 110 of the printed circuit board 100. As shown, two SMT feet 20 are provided with the connector 10, although a single SMT foot could be used. In a similar fashion, three or more SMT feet 20 may extend from a single SMT connector 10 to the surface 110 of the printed circuit board 100. At least one of the SMT feet 20 has a plated coined edge surface 22 that increases the plated surface area of the SMT foot 20 for a solder fillet to be applied and attach the foot 20 to the printed circuit board 100.

The SMT connector 10, including the foot 20, is cut and formed from pre-plated sheet stock 70 (FIG. 5). That is, the connector 10 is initially formed from a sheet of metallic base material pre-plated on at least one side with a layer of a corrosion-resistant conductive material. Typically, the sheet 70 is pre-plated on the top and bottom sides 72, 74 of the sheet 70. The base material may be any conductive material suitable for use as a surface mount device and is typically copper or an alloy thereof. Exemplary copper alloys include, without limitation, bronze, phosphor bronze, brass, tin brass, leaded brass, beryllium copper, copper silicon nickel, and combinations thereof. Other exemplary base materials include copper-iron alloys and iron-nickel alloys.

The plating layer may be any layer of corrosion-resistant, conductive material, such as tin, tin-lead alloy, zinc, nickel, gold, silver, platinum, palladium, alloys thereof, and combinations thereof, by way of example only.

In order to manufacture the connector 10 to its desired shape, the connector is cut and formed from the pre-plated sheet stock 70 in any manner customarily used to create surface mount devices from sheet stock. These manufacturing operations result in creating new, unplated surfaces by exposing underlying base material in the formed connector 10, such as the side surfaces 24 of the foot 20 (better seen in FIG. 2). Conversely, the surfaces of the top and bottom sides 72, 74 of the sheet 70 are generally unaltered by manufacturing operations, and thus provide other surfaces of the formed connector 10 that remain plated, such as the top and bottom surfaces 26, 28 of the SMT foot 20. In the embodiment shown in FIG. 2, the unplated side surfaces 24 are shown with cross-hatching, but it will be appreciated that this is for illustration only and is not meant to suggest that no other surfaces of the connector 10 are unplated as a result of manufacturing operations. The exposed base material, as described above, is typically a copper alloy or other corrosion susceptible material that does not support a satisfactory solder joint.

It has been determined by the inventors that by using pre-plated stock to make surface mount devices, the deficiencies of the exposed surfaces of base material that result from production can be overcome by subsequently imparting a coined (also referred to as swaged) edge surface 22 to the intersection of the plated bottom surface 28 and the unplated side surface 24 of the SMT foot 20. This causes the still-plated bottom surface 28 of the foot 20 to essentially “wrap” around the side of the foot 20, decreasing the area of the unplated side surface 24. In doing so, a new, plated, coined edge surface 22 is created to which a solder fillet will be wetted during the soldering operation. As a result, an acceptable solder joint that at least meets IPC J-STD-001D and has a wetting angle less than 90 degrees may be created.

As also illustrated in FIG. 2, the SMT foot 20 may include an optional jog portion 25 that extends away from the connector receptacle portion 15 of the connector 10 downward to the foot 20.

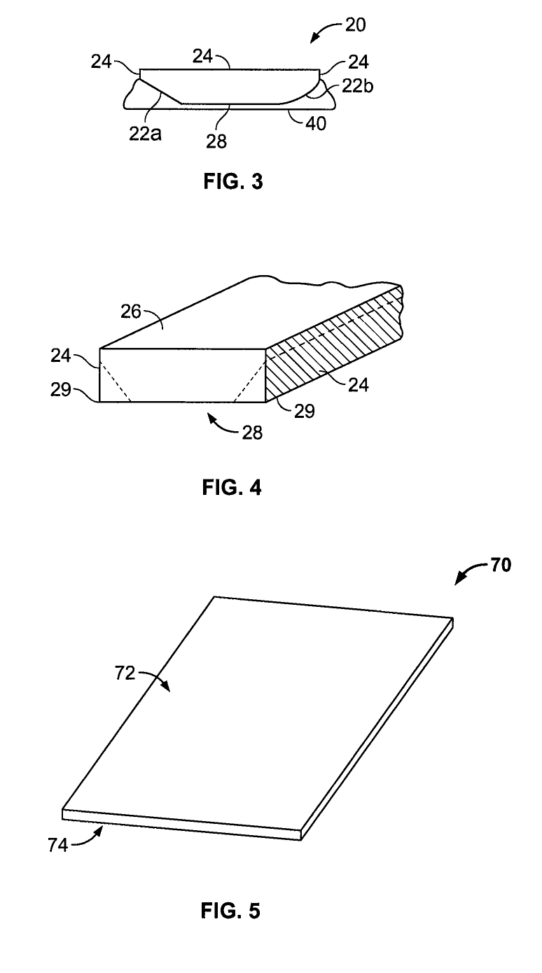

The coined edge surface 22 may be a beveled edge surface 22a or it may be a smooth curve resulting in a radial edge surface 22b. As shown in FIG. 3, the foot 20 may have a combination of both styles of coined edge surfaces 22, although both coined edge surfaces 22 are ordinarily of the same style. FIG. 3 also illustrates how a solder fillet 40 wets the plated coined edge surfaces 22, but generally not the unplated side surfaces 24, to yield an acceptable solder joint when the SMT foot 20 is soldered to the surface 110 of a printed circuit board 100. It will be appreciated that while the SMT foot 20 is illustrated as being soldered to the surface 110 of a printed circuit board 100, the SMT foot 20 may also be attached to the surface of a molded interconnect device or any other suitable surface of an electronic device.

As will be appreciated by those of ordinary skill in the art, soldering generally involves applying heat to the parts to be joined in the presence of solder wire, causing the solder to melt and be drawn into the joint by capillary action and to bond to the materials to be joined by wetting action after the metal cools. Exemplary embodiments of the invention may be used with both lead-base and lead-free (e.g. tin-base) solders.

FIG. 4 shows an example of an SMT foot 20 after the cutting and forming operation, but prior to the swaging operation to impart the coined edge surfaces 22. Any suitable swaging process may be used. According to one embodiment, the coined edge surface 22 is produced by a swaging process that uses an automated die to compress the plated bottom surface 28 of the foot 20 toward the top surface 26 at corner edges 29 that define the interface of the bottom surface 28 and the unplated side surfaces 24 (again shown with cross-hatching for illustration purposes). The boundaries of the new coined edge surface 22 to be created are shown in broken line. The corner edges 29 are compressed along at least a portion of the length of the foot 20, and the coined edge surface 22 may extend the entire length of the SMT foot 20.

In one embodiment, the foot 20 is about 0.090 inches long, about 0.050 inches wide, and about 0.0125 inches high. It will be appreciated, however, that the dimensions of the foot 20 may vary based on the overall dimensions of the connector 10, as well as the application in which the connector 10 will be used. It will further be appreciated that the original dimensions may be altered slightly by the swaging operation, which may, for example, cause minor bulging in the top and bottom surfaces 26, 28 of the foot 20. After swaging, the height of the coined edge surface 22 may be about 20% to about 70% of the height of the foot 20, typically at least about 30%, and more typically about 50% of the height of the foot 20. For example, with respect to the 50% embodiment, if the pre-coined height of the foot 20 is 0.010 inches, the interface of the new coined edge surface 22 and the remaining side surface 24 is at a height of about 0.005 inches above the plane in which the bottom surface 28 is situated.

While the foregoing specification illustrates and describes exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A surface mount device comprising:
a surface mount device having at least one surface mount foot extending therefrom, the surface mount foot comprising
a conductive base material, and
a corrosion-resistant conductive material at least partially overlying the conductive base material;
wherein the surface mount foot has a top surface, a plated bottom surface, two unplated side surfaces, and at least one plated coined edge surface, the plated coined edge surface intermediate the plated bottom surface and an unplated side surface.

2. The surface mount device of claim 1, wherein the coined edge surface is beveled.

3. The surface mount device of claim 1, wherein the coined edge surface is radial.

4. The surface mount device of claim 1, further comprising a connector receptacle portion and a jog portion extending from the connector receptacle portion to the surface mount foot.

5. The surface mount device of claim 1, wherein the corrosion-resistant conductive material overlying the base material is a metal selected from the group consisting of tin, zinc, nickel, gold, silver, platinum, palladium, alloys thereof, and combinations thereof.

6. The surface mount device of claim 1, wherein the conductive base material is copper or an alloy thereof.

7. The surface mount device of claim 1, wherein the surface mount foot has a height, and wherein the height of an interface of the coined edge surface and the side surface above a plane in which the bottom surface is situated is about 20% to about 70% of the surface mount foot height.

8. The surface mount device of claim 7, wherein the height of the interface of the coined edge surface and the side surface above the plane in which the bottom surface is situated is at least about 30% of the surface mount foot height.

9. The surface mount device of claim 7, wherein the height of the interface of the coined edge surface and the side surface above the plane in which the bottom surface is situated is about 50% of the surface mount foot height.

10. The surface mount device of claim 1, wherein the top surface of the surface mount foot is plated.

11. A method for making a surface mount device comprising:
providing a piece of pre-plated conductive sheet stock comprising a conductive base material and a corrosion-resistant conductive plating material different from the conductive base material overlying the conductive base material;
cutting and forming the piece of pre-plated conductive sheet stock to create a surface mount device having a surface mount foot extending therefrom, the surface mount foot having a top surface, a plated bottom surface and at least one unplated side surface intermediate the top surface and the bottom surface; and
swaging the plated bottom surface to create a plated coined edge surface intermediate the unplated side surface and the plated bottom surface of the surface mount foot.

12. The method of claim 11, wherein the step of providing comprises providing the piece of pre-plated conductive sheet stock comprising
a conductive base material selected from the group consisting of copper, copper alloys, iron-copper alloys, and iron-nickel alloys, and
a corrosion-resistant conductive plating material selected from the group consisting of tin, zinc, nickel, gold, silver, platinum, palladium, alloys thereof, and combinations thereof.

13. The method of claim 11, wherein the step of swaging comprises using an automated die to compress the bottom surface toward the top surface at a corner edge that defines an interface of the bottom surface and the unplated side surface.

14. The method of claim 11, wherein the swaging produces a beveled coined edge surface.

15. The method of claim 11, wherein the swaging produces a radial coined edge surface.

16. The method of claim 11, wherein the swaging produces an interface of the coined edge surface and the side surface having a height about 20% to about 70% of the height of the surface mount foot.

17. The method of claim 11, wherein the swaging produces an interface of the coined edge surface and the side surface having a height of about 50% of the height of the surface mount foot.

18. A method for attaching a surface mount device to an electronic device comprising:
providing a piece of pre-plated conductive sheet stock comprising a conductive base material and a corrosion-resistant conductive plating material different from the conductive base material overlying the conductive base material;
cutting and forming the piece of pre-plated conductive sheet stock to create a surface mount device having a surface mount foot extending therefrom, the surface mount foot having a plated top surface and a plated bottom surface and having at least one unplated side surface intermediate the top surface and the bottom surface;
swaging the plated bottom surface to create a plated coined edge surface intermediate the unplated side surface and the plated bottom surface of the surface mount foot; and
soldering the surface mount foot to an electronic device to produce a solder joint having a wetting angle of less than 90 degrees.

19. The method of claim 18, wherein the electronic device is a printed circuit board.

20. The method claim 18, wherein the step of soldering comprises soldering with a lead-free solder.
